(19) United States
(12) Patent Application Publication
(10) Pub. No.: US 2014/0151664 A1
(43) Pub. Date: Jun. 5, 2014

(54) BENZOIMIDAZOLE DERIVATIVE, ORGANIC ELECTROLUMINESCENCE MATERIAL AND ORGANIC ELECTROLUMINSCENCE DEVICE

(71) Applicant: Samsung Display Co., Ltd., Yongin-City (KR)

(72) Inventor: Shuri SATO, Yongin-City (KR)

(73) Assignee: Samsung Display Co., Ltd., Yongin-City (KR)

(21) Appl. No.: 14/093,759

(22) Filed: Dec. 2, 2013

(30) Foreign Application Priority Data
Nov. 30, 2012 (JP) 2012-263786

(51) Int. Cl. H01L 51/00

(52) U.S. Cl. CPC H01L 51/0072
USPC 257/40; 548/305.1

(57) ABSTRACT

A benzoimidazole derivative includes two carbazole substituents connected to each other, and a benzoimidazole substituent connected to a benzene ring of one of the carbazole substituents through an aryl group.

### CROSS-REFERENCE TO RELATED APPLICATION

Korean Patent Application No. 2012-263786, filed on Nov. 30, 2012, in the Japanese Intellectual Property Office, and entitled: “Benzoimidazole Derivative, Organic Electroluminescence Material, and Organic Electroluminescence Device,” is incorporated by reference herein in its entirety.

### BACKGROUND

1. Field

Embodiments relate to an organic electroluminescence device and compounds used in the organic electroluminescence device.

2. Description of the Related Art

In recent years, organic electroluminescence (EL) displays are one type of image displays that have been actively developed. Unlike a liquid crystal display and the like, the organic EL display is a self-luminescent display in which holes injected from a positive electrode and electrons injected from a negative electrode are recombined in a emission layer to thus emit light from a light-emitting material including an organic compound of the emission layer, thereby displaying an image.

An organic electroluminescence device (hereinafter referred to as an organic EL device) may include a plurality of layers having different properties such as an emission layer and a carrier (hole, electron) transport layer to the emission layer.

### SUMMARY

Embodiments are directed to benzoimidazole derivative including two carbazole substituents connected to each other, and a benzoimidazole substituent connected to a benzene ring of one of the carbazole substituents through an aryl group.

The benzoimidazole derivative may be represented by following Formula 1:

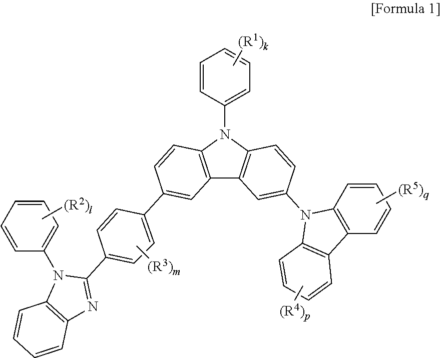

wherein, R¹ to R⁵ may represent an alkyl group, an aryl group, or a heteroaryl group that replaces a hydrogen of a respective benzene ring,

k, l, m, p, and q may each independently represent an integer of 0 to 4, and denote a number of the R¹, R², R³, R⁴, and R⁵, respectively,

when any of k, l, m, p, and q is greater than or equal to 1, each of (R¹)₁ through (R¹)ₖ, (R²)₁ through (R²)₁, (R³)₁, through (R³)ₘ, (R⁴)₁, through (R⁴)ₚ, or (R⁵)₁, through (R⁵)_{q}, may be the same or different.

Embodiments are also directed to an organic electroluminescence device, including a positive electrode, a negative electrode, and organic thin layers between the positive electrode and the negative electrode. At least one layer of the organic thin layers includes the benzoimidazole derivative described above.

The organic thin layer including the benzoimidazole derivative may be at least one layer selected from an emission layer, an intermediate layer, and a hole transport layer.

The organic thin layer including the benzoimidazole derivative may be the emission layer, and a host material of the emission layer includes the benzoimidazole derivative.

The organic thin layer including the benzoimidazole derivative may be the intermediate layer, and the intermediate layer may not include a dopant.

A lighting system may include the organic electroluminescence device as described above.

An organic electroluminescence display may include the organic electroluminescence device as described above.

### BRIEF DESCRIPTION OF THE DRAWINGS

Features will become apparent to those of skill in the art by describing in detail exemplary embodiments with reference to the attached drawings in which:

FIG. 1 illustrates a schematic cross-sectional view depicting an embodiment of the structure of an organic EL device; and

FIG. 2 illustrates a schematic diagram of an organic EL device manufactured by using a benzoimidazole derivative as an organic light-emitting material according to an embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present.

A compound according to embodiments may be a benzoimidazole derivative including two carbazole substituents bonded to each other and a benzoimidazole substituent bonded through an aryl group to a benzene ring of one of the two carbazole substituents.

The compound according to embodiments may be represented by the following Formula 1.

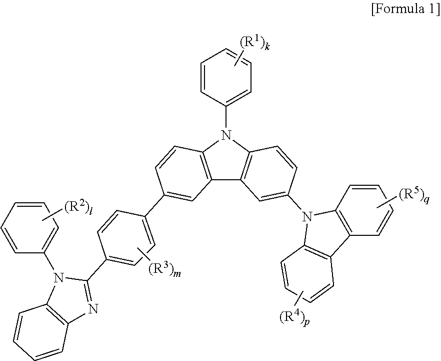

In Formula 1, R¹ to R⁵ may independently represent an alkyl group, an aryl group, or a heteroaryl group replacing a hydrogen of a respective benzene ring.

k, l, m, p, and q each independently represent an integer of 0 to 4, and denote the respective number of the R¹ to R⁵′.

When any of k, l, m, p, and q is greater than or equal to 1, each of (R¹)₁ through (R¹)ₖ, (R²)₁ through (R²)₁, (R³)₁ through (R³)ₘ, (R⁴)₁ through (R⁴)ₚ, or (R⁵)₁, through (R⁵)_{q}, may be the same or different.

The alkyl group may be a methyl group, an ethyl group, a propyl group, an isopropyl group, a butyl group, an isobutyl group, a sec-butyl group, a tert-butyl group, a pentyl group, an isoamyl group, a hexyl group, a cyclohexyl group, an heptyl group, an octyl group, a 2-ethyl hexyl group, a nonyl group, a decyl group, a 3,7-dimethyloctyl group, a dodecyl group, a trifluoromethyl group, a pentafluoroethyl group, a perfluorobutyl group, a perfluorohexyl group, a perfluorooctyl group, or the like.

The term “aryl group” may refer to an atomic group excluding one hydrogen atom from a monocyclic, dicyclic, or tricyclic aromatic hydrocarbon. The aryl group may have a substituent. The term “heteroaryl” refers an atomic group excluding one hydrogen atom from a monocyclic, dicyclic, or tricyclic aromatic hydrocarbon including one or more hetero atoms. The heteroaryl group may have a substituent.

The aryl group may be a phenyl group, a biphenylyl group, a C₁ to C₁₂ alkoxyphenyl group, a C₁ to C₁₂ alkylphenyl group, a 1-naphthyl group, a 2-naphthyl group, 1-anthracenyl group, a 2-anthracenyl group, a 9-anthracenyl group, a 2-fluorenyl group, a pentafluorophenyl group, a biphenylyl group, a C₁ to C₁₂ alkoxybiphenylyl group, a C_{I} to C₁₋₂ alkyl biphenylyl group, or the like.

The heteroaryl group may be a thienyl group, a benzothienyl group, a furyl group, a benzofuryl group, a pyrrolyl group, an imidazolyl group, a benzoimidazolyl group, a thiazolyl group, a benzothiazolyl group, an isothiazolyl group, a benzoisothiazolyl group, a pyrazolyl group, an oxazolyl group, a benzoxazolyl group, an isoxazolyl group, a benzoisoxazolyl group, an isothiazolyl group, a triazolyl group, a benzotriazolyl group, a thiadiazolyl group, an oxadiazolyl group, a pyridinyl group, a pyridazinyl group, a pyrimidinyl group, a triazinyl group, an indolyl group, an indazolyl group, a carbazolyl group, or the like.

The alkoxy group may be a methoxy group, an ethoxy group, or the like.

The benzoimidazole derivative has according to embodiments has a structure that includes carbazole groups. By including carbazole groups, hole transport properties may be improved. An organic EL device manufactured by using the benzoimidazole derivative as an organic light-emitting material may have improved light-emitting efficiency.

As examples, the benzoimidazole derivative may be one of Compounds No. 1-9, below. Compounds No. 1-9

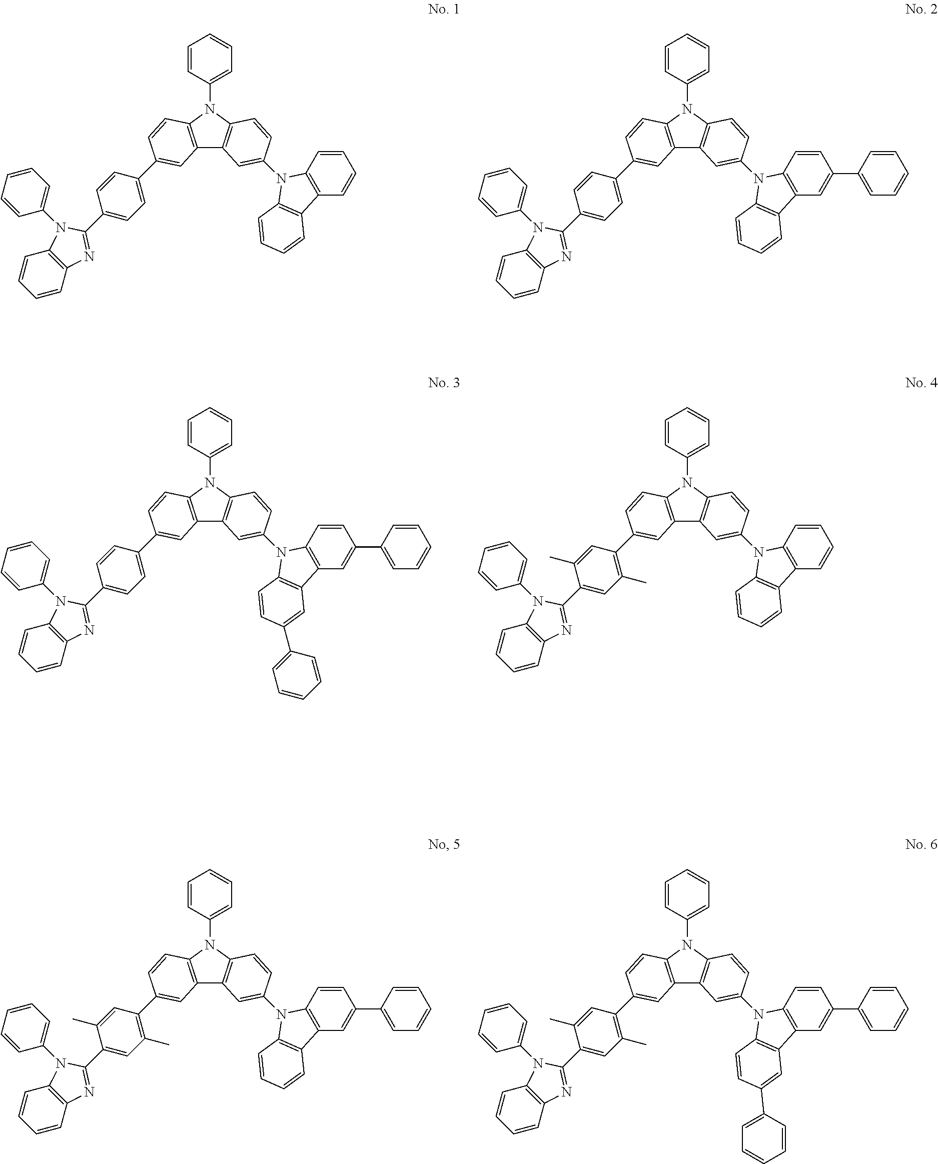

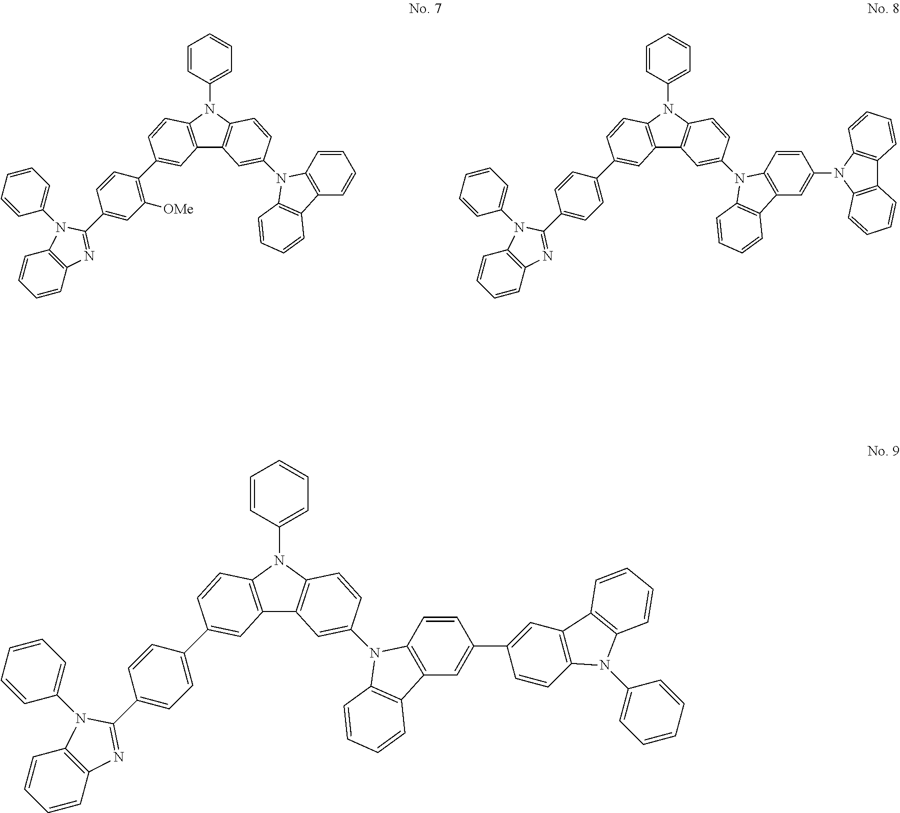 [SMILES: COc1cc(-c2nc3ccccc3n2-c2ccccc2)ccc1-c1ccc2c(c1)c1cc(-n3c4ccccc4c4ccccc43)ccc1n2-c1ccccc1 ; c1ccc(-n2c(-c3ccc(-c4ccc5c(c4)c4cc(-n6c7ccccc7c7cc(-n8c9ccccc9c9ccccc98)ccc76)ccc4n5-c4ccccc4)cc3)nc3ccccc32)cc1 ; c1ccc(-n2c(-c3ccc(-c4ccc5c(c4)c4cc(-n6c7ccccc7c7cc(-c8ccc9c(c8)c8ccccc8n9-c8ccccc8)ccc76)ccc4n5-c4ccccc4)cc3)nc3ccccc32)cc1]

Referring to Formula 1, compound No. 1 is provided where k=l=m=p=q=0. Compound No. 2 is provided where k=l=m=p=0, R⁵ is a phenyl group, and q=1. Compound No. 3 is provided where k=l=m=0, R⁴ and R⁵ are phenyl groups, and p=q=1.

Compound No. 4 is provided where k=l=p=q=0, m=2, and R³ represents two methyl groups replacing two hydrogen atoms at para sites of the benzene ring connecting the benzoimidazole substituent and one of the carbazole substituents. In other implementations, each R³ may be an alkyl group other than methyl or may be a phenyl group. Compound No. 5 is provided where k=l=p=0, m=2, R³ represents two methyl groups replacing two hydrogen atoms at para sites of the benzene ring connecting the benzoimidazole substituent and one of the carbazole substituents, R⁵ is a phenyl group, and q=1. In other implementations, each R³ may be an alkyl group other than methyl or may be a phenyl group. Compound No. 6 is provided where k=l=0, m=2, R³ represents two methyl groups replacing two hydrogen atoms at para sites of the benzene ring connecting the benzoimidazole substituent and one of the carbazole substituents, R⁴ and R⁵ are phenyl groups. In other implementations, each R³ may be an alkyl groups other than methyl or may be a phenyl group.

Compound No. 7 is provided where k=l=p=q=0, m=1, and R³ is a methoxy group that replaces a hydrogen of the benzene ring connecting the benzoimidazole substituent and one of the carbazole substituents. In other implementations, R³ may be an alkoxy group other than methoxy. Compound No. 8 is provided where k=l=m=p=0, R⁵ is a carbazole group, and q=1. Compound No. 9 is provided where k=l=m=p=0, R⁵ is a phenylcarbazole group, and q=1. In other implementations, R⁵ may be a carbazole derivative other than phenylcarbazole, such as 9-phenylcarbazole, N-ethylcarbazole (ECZ), (2-[4-(9H-carbazol-9-yl)phenyl]biphenyl-4,4′-diamine, N-substituted carbazole of phenylcarbazole and N-hydroxyethylcarbazole, etc., 4,4′-bis(9H-carbazol-9-yl)biphenyl (CBP), N-nitrosocarbazole, N-nitroso-3-nitrocarbazole, 3-nitrocarbazole, an acylation derivative of carbazole, or the like.

In addition, other compounds according to implementations may be provided by substituting one or more hydrogen atoms at one of R¹, R², R³ and R⁴ positions other than R⁵ position Formula 1 with a carbazole derivative.

Embodiment of Organic EL Device

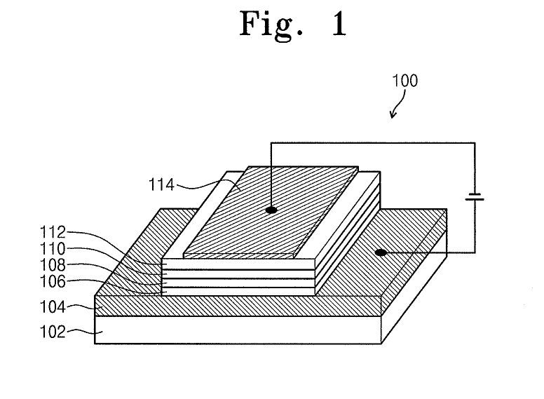

The benzoimidazole derivative according to embodiments may be used as a material for an organic EL device. The organic EL device may have, for example, the structure illustrated in FIG. 1.

FIG. 1 illustrates a schematic cross-sectional view depicting an embodiment of the structure of an organic EL device including a benzoimidazole derivative as a material for the organic EL device according to embodiments. An organic EL device 100 may include a substrate 102, such as a glass substrate, a positive electrode 104 on the substrate 102, a hole injection layer 106 on the positive electrode 104, a hole transport layer 108 on the hole injection layer 106, an emission layer 110 on the hole transport layer 108, an electrode transport layer 112 on the emission layer 110, and a negative electrode 114 on the electron transport layer 112. The electron transport layer 112 may function as an electron injection layer.

By using the benzoimidazole derivative according to embodiments as at least one material among a hole injection layer material, a hole transport layer material, and an emission layer material of the hole injection layer 106, the hole transport layer 108, and the emission layer 110, for constituting an organic EL device, an organic EL device having high efficiency and long life may be obtained.

Particularly, when the emission layer material includes the benzoimidazole derivative according to embodiments, a color difference may be restrained when continuously driving the organic EL device, and a color difference of an organic EL display including the organic EL device may be also restrained. The carbazole group may have a high hole transport performance, and the molecules thereof may be rigid. Accordingly, the benzoimidazole derivative of which at least one hydrogen positioned at R¹, R², R³, R⁴ and R⁵ is substituted with the carbazole group may have good heat-resistance, and may contribute to attaining a high efficiency and long life of the organic EL device.

The benzoimidazole derivative accordingly to embodiments of which at least one hydrogen positioned at R¹, R², R³, R⁴ and R⁵ is substituted with a carbazole group may be appropriately used as a material of the emission layer, the hole transport layer, or the hole injection layer.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### EXAMPLES

With respect to the benzoimidazole derivative according to embodiments, an example of synthesizing compound No. 1 will be explained herein below, as an illustration.

Synthesis of compound No. 1

Compound No. 1 was synthesized as follows.

Synthesis of Compound A

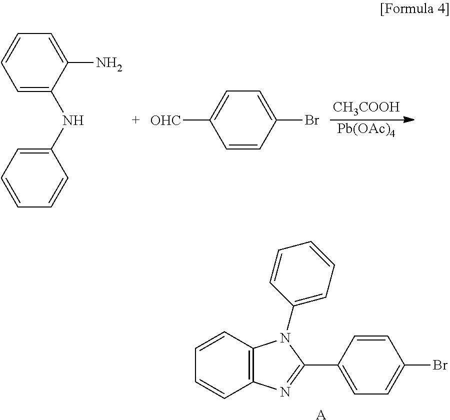

5.0 g of 4-dibromobenzaldehyde and 3.83 g of N-phenyl-o-phenylenediamine were put into a 500 ml round-bottomed flask, and 50 ml of acetic acid was added and stirred at room temperature for 30 minutes. Then, 10 g of lead acetate (IV) was added and stirred at room temperature for 12 hours. After completing the reaction, acetic acid was removed under reduced pressure. The reactant was dissolved in methylene chloride and washed five times using water. An organic solution was dried using anhydrous magnesium sulfate, and solvents were removed to obtain a solid. The solid was purified in a methylene chloride solvent using silica gel column chromatography. The thus obtained product was recrystallized in a mixed solvent of methylene chloride and hexane (1:6) to obtain 3.0 g of Compound A as a white solid.

Synthesis of Compound B

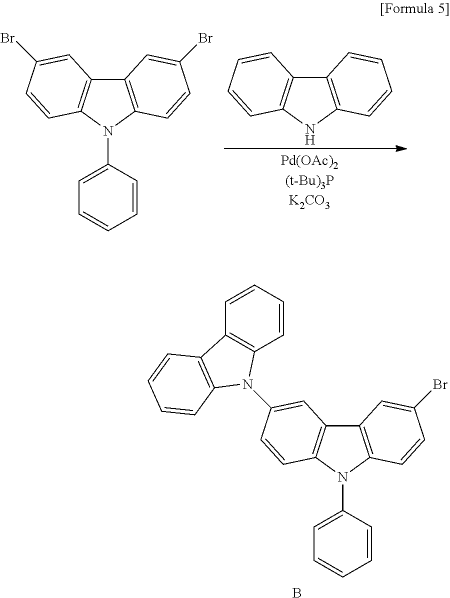

Into a 100 ml of three-necked flask, 1.0 g of 9H-carbazole, 2.0 g of 3,6-dibromo-9-phenylcarbazole, 1.1 mg of palladium (II) acetate (Pd(OAc)₂), 3.0 mg of tri-tert-butylphosphine (t-Bu)₃P, 2.1 g of potassium carbonate (K₂CO₃) were added and heated and stirred in 50 ml xylene at 120° C. for 12 hours. After cooling in the atmosphere, water was added, and an organic layer was separated. Organic solvents were distilled off. The crude product thus obtained was purified by silica gel column chromatography (using a mixed solvent of dichloromethane and hexane) and recrystallized by using a mixed solvent of toluene and hexane to obtain 2.0 g of Compound B as a white solid.

Synthesis of Compound C

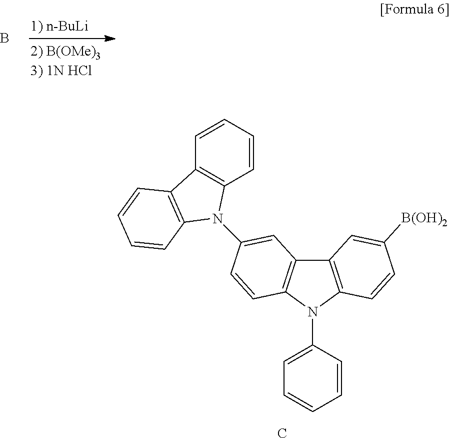

Under an argon gas atmosphere, the temperature of a 300 ml three-necked flask was maintained to −78° C., and 7.2 g of Compound B was dissolved in anhydrous THF. 1.6M of an n-butyl lithium-n-hexane solution (1.1 eq) was dropped and stirred for 1 hour. Trimethoxy borane (B(OMe)₃, 1.3 eq) was added and stirred for 2 hours. The temperature of the reactant was increased to room temperature. 200 ml of 1N hydrochloric acid was added into the reactant and stirred for 3 hours. Then, an organic layer was separated, and solvents were distilled off. Hexane was added into the crude product thus obtained, and the precipitated product was filtered to obtain 4.8 g of Compound C as a white solid.

Synthesis of Compound No. 1

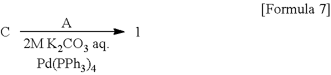

Under an argon atmosphere, 2.0 g of Compound C was added to a 200 ml three-necked flask, along with Compound A (1 eq), 20 ml of an aqueous potassium carbonate solution, and tetrakistriphosphinepalladium (Pd(PPh₃)₄) (0.07 eq). The reactant was refluxed in 80 ml of tetrahydrofuran (THF) and stirred for 6 hours. The reactant was cooled to room temperature, and an organic layer was separated and purified by silica gel column chromatography (using a mixed solvent of chloroform and hexane). Recrystallization was performed using a mixed solvent of toluene and hexane to obtain 1.8 g of Compound No. 1 as a white solid.

Organic EL Device

Hereinafter, the constitution and effect of an organic EL device using Compound No. 1 in an emission layer will be explained.

### Example 1

The manufacture of the organic EL device according to Examples 1 and 2, and Comparative Examples 1 and 2 was performed as follows. A thin film positive electrode was formed using ITO by a sputtering method to about 100 nm on a glass substrate and patterned. The glass substrate was washed using ultrasonic waves in isopropyl alcohol and pure water respectively for 5 minutes. The substrate was installed in a vacuum deposition apparatus, and a hole injection layer thin film was formed to a thickness of about 60 nm by depositing 4,4′,4″-tris(N,N-(1-naphthyl)phenylamino)triphenylamine (TNATA). Then, a hole transport layer thin film was formed using N,N′-bis(1-naphthyl)-N,N′-bisphenyl benzidine (NPD). An emission layer was formed to a thickness of about 40 nm by co-depositing tris(2-phenylpyridine)iridium (Ir(ppy)₃) and Compound No. 1, at a volume ratio of 10:90. Then, an electron transport layer was formed by depositing a tris(8-quinolinato)aluminum thin film to a thickness of about 25 nm (, an electron injection layer was formed by depositing a fluorinated lithium thin film to a thickness of about 1 nm, and a negative electrode layer was formed by depositing an aluminum thin film to a thickness of about 100 nm. The substrate was taken out from the vacuum deposition apparatus and encapsulated using glass to manufacture an organic EL device 101.

### Comparative Examples 1 and 2

An organic EL device 101 was manufactured by performing a similar process as described in Example 1 except for using Comparative Compound 1 instead of Compound No. 1 for forming an emission layer.

Another organic EL device 101 was manufactured by performing a similar process as described in Example 1 except for using Comparative Compound 2 instead of Compound No. 1 for forming an emission layer.

The structures of the compounds constituting the material of the emission layer of the organic EL device of Comparative Examples 1 and 2 are illustrated below. Comparative Compound 1 is a compound having a combined structure of a phenyl carbazole group and a carbazole group using a phenyl group as a linker. Comparative Compound 2 has a directly combined structure of a phenyl carbazole group and a carbazole group.

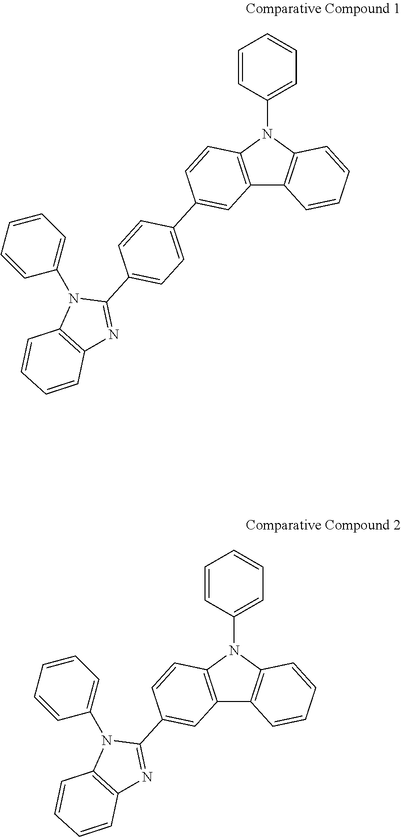 [SMILES: c1ccc(-n2c(-c3ccc(-c4ccc5c(c4)c4ccccc4n5-c4ccccc4)cc3)nc3ccccc32)cc1 ; c1ccc(-n2c(-c3ccc4c(c3)c3ccccc3n4-c3ccccc3)nc3ccccc32)cc1]

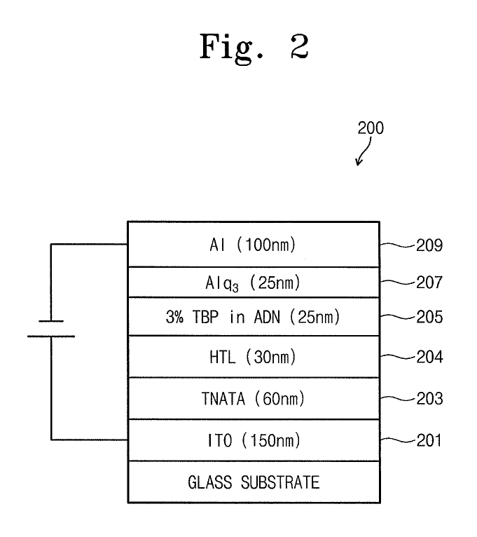

The schematic diagram of an organic EL device 200 manufactured by Examples 1 and 2, and Comparative Examples 1 and 2 is illustrated in FIG. 2. The manufactured organic EL device 200 includes a positive electrode 201, a hole injection layer 203 on the positive electrode 201, a hole transport layer 204 on the hole injection layer 203, an emission layer 205, an electron transport layer 206 on the emission layer 205, an electron injection layer 207, and a negative electrode 209 on the electron injection layer 207.

With respect to the organic EL devices, current efficiency at about 9,000 nit (unit: cd/A), and a driving voltage (unit: V), and luminance half-life (unit: hour) were evaluated. In addition, CIE 1931 chromaticity (x, y) values before and after evaluating the luminance half-life were compared.

The device performance of the organic EL devices manufactured by Examples 1, and Comparative Examples 1 and 2 is illustrated in the following Table 1. The values shown in FIG. 1 are relative values when the value for Example 1 was set to 100%.

TABLE 1

| | | | | | | X | Y |
|---|---|---|---|---|---|---|---|
| | | | Driving | Current | Luminance | difference | difference |
| | Organic | Host | voltage | efficiency | half-life | before and | before and |
| | EL device | material | (%) | (%) | (%) | after life | after life |
| Example 1 | 101 | Compound | 100 | 100 | 100 | <0.001 | 0.001 |
| | | No. 1 | | | | | |
| Comparative | 201 | Comparative | 120 | 90 | 80 | 0.003 | 0.010 |
| Example 1 | | Compound 1 | | | | | |
| Comparative | 202 | Comparative | 115 | 90 | 80 | 0.005 | 0.009 |
| Example 2 | | Compound 2 | | | | | |

The organic EL device according to Example 1 included an emission layer including the benzoimidazole derivative according to embodiments. In Table 1, the organic EL device according to Example 1 had higher light-emitting efficiency, and had longer life by at least 1.2 times and above when compared to the EL devices of Comparative Examples 1 and 2.

The benzoimidazole derivative according to embodiments maintained good carrier balance. Accordingly, an organic EL device including the benzoimidazole derivative may not undergo a color change during driving, and may have high efficiency and long life, as may be seen in the device performance of the organic EL device of Example 1.

In the above-described embodiments, organic EL devices including a benzoimidazole derivative according to embodiments in an emission layer material have been illustrated. The benzoimidazole derivative according to embodiments may be also used in a hole transport layer material. In addition, the benzoimidazole derivative may be used in other light-emitting devices or light-emitting apparatuses.

By way of summation and review, for industrial use of an organic EL device, a high efficiency and long life are desirable. In designing the organic EL device, an appropriate maintenance of the carrier balance of the holes and electrons, which are transported to the emission layer and recombined, is desirable to obtain an organic EL device having good light-emitting efficiency and long life. A (bipolar) host material having hole transport properties and electron transport properties is desirable.

However, a general host material may have low bipolar properties, and may have issues relating to the light-emitting efficiency and the life of an organic EL device.

When the organic EL device is continuously driven for a long time, it is desirable that there be no color difference from an initial color exhibited at initial driving. In order to emit light with good carrier balance, a method of using a mixture of a hole transport host and an electron transport host may be used. However, the development of two kinds of host materials having the same deterioration properties is difficult. When two kinds of host materials having different deterioration properties are used, the carrier balance may be changed during driving and the color may be changed.

Through using the benzoimidazole derivative according to embodiments as a host material having good bipolar properties, good carrier balance may be maintained, and the generation of a color difference during driving may be avoided. A device having high efficiency and long life may be obtained. Accordingly, embodiments provide an organic EL device exhibiting little color difference during continuous driving and having improved light-emitting efficiency, and an organic light-emitting material for accomplishing the organic EL device.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope thereof as set forth in the following claims.

What is claimed is:

1. A benzoimidazole derivative, comprising:
two carbazole substituents connected to each other, and
a benzoimidazole substituent connected to a benzene ring of one of the carbazole substituents through an aryl group.

2. The benzoimidazole derivative as claimed in claim 1, wherein the benzoimidazole derivative is represented by following Formula 1: 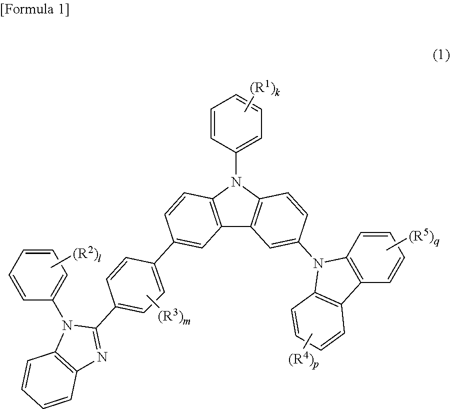
wherein, R¹ to R⁵ represent an alkyl group, an aryl group, or a heteroaryl group that replaces a hydrogen of a respective benzene ring,
k, l, m, p, and q each independently represent an integer of 0 to 4, and denote a number of the R¹, R², R³, R⁴, and R⁵, respectively,
when any of k, l, m, p, and q is greater than or equal to 1, each of (R¹)₁ through (R¹)ₖ, (R²)₁ through (R²)₁, (R³)₁, through (R³)ₘ, (R⁴)₁, through (R⁴)ₚ, or (R⁵)₁, through (R⁵)_{q}, are the same or different.

3. An organic electroluminescence device, comprising:
a positive electrode,
a negative electrode, and
organic thin layers between the positive electrode and the negative electrode,
wherein at least one layer of the organic thin layers includes the benzoimidazole derivative described in claim 1.

4. The organic electroluminescence device as claimed in claim 3, wherein the organic thin layer including the benzoimidazole derivative is at least one layer selected from an emission layer, an intermediate layer, and a hole transport layer.

5. The organic electroluminescence device as claimed in claim 4, wherein:
the organic thin layer including the benzoimidazole derivative is the emission layer, and
a host material of the emission layer includes the benzoimidazole derivative.

6. The organic electroluminescence device as claimed in claim 4, wherein:
the organic thin layer including the benzoimidazole derivative is the intermediate layer, and
the intermediate layer does not include a dopant.

7. A lighting system, comprising the organic electroluminescence device as claimed in claim 3.

8. An organic electroluminescence display, comprising the organic electroluminescence device as claimed in claim 3.
